(19) United States
(12) Patent Application Publication
(10) Pub. No.: US 2026/0311330 A1
(43) Pub. Date: Oct. 8, 2026

(54) Systems and Methods for Uncertainty-Aware-Single-Particle Cryo-EM Data Collection Using Online Feedback

(71) Applicant: REGENTS OF THE UNIVERSITY OF MICHIGAN, Ann Arbor, MI (US)

(72) Inventors: Michael Cianfrocco, Ann Arbor, MI (US); Ambuj Tewari, Ann Arbor, MI (US); Lai Wei, Ann Arbor, MI (US)

(21) Appl. No.: 19/575,559

(22) Filed: Mar. 23, 2026

Related U.S. Application Data
(60) Provisional application No. 63/775,777, filed on Mar. 21, 2025.

(51) Int. Cl. G06T 7/00; H01J 37/22; H01J 37/26

(52) U.S. Cl. CPC G06T 7/0012; H01J 37/222; H01J 37/26; G06T 2200/24; G06T 2207/10056; G06T 2207/20081; G06T 2207/30168; H01J 2237/002

(57) ABSTRACT

A system and method are disclosed for automating cryogenic electron microscopy (cryo-EM) data collection by optimizing a sampling strategy. The system identifies, from patch-level images taken by a cryo-EM instrument, a plurality of holes within a cryo-EM grid, each representing a candidate data collection point. The system predicts an expected reward for each identified hole based on features extracted from the patch-level images. The system determines, using stochastic approximation, a dynamically adjusted threshold quality score representing an estimated optimal time-average reward. Holes are selected from the identified plurality based on the expected reward by minimizing an objective function that depends on the dynamically adjusted threshold quality score. The dynamically adjusted threshold quality score may be based at least in part on observed rewards from the selected holes and microscope operation times.

### CROSS-REFERENCE TO RELATED APPLICATIONS

This application claims the benefit of U.S. Provisional Patent Application No. 63/775,777, entitled “SYSTEM AND METHODS FOR UNCERTAINTY-AWARE SINGLE-PARTICLE CRYO-EM DATA COLLECTION USING ONLINE FEEDBACK,” filed Mar. 21, 2025. U.S. Provisional Patent Application No. 63/775,777 is hereby expressly incorporated by reference herein in its entirety.

### STATEMENT OF GOVERNMENT INTEREST

This invention was made with government support under GM143805 awarded by the National Institutes of Health. The government has certain rights in the invention.

### FIELD OF THE INVENTION

The present aspects relate to techniques for Cryo-EM data collection, and more particularly, to techniques using an uncertainty-aware method for single particle Cryo-EM data collection using online feedback.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Single-particle cryo-electron microscopy (cryo-EM) has become a powerful tool in structural biology for elucidating the structures of biological macromolecules. Cryo-EM is one of the fastest-growing areas of structural biology, enabling 3D structure determination of important macromolecular complexes and membrane proteins. Despite the recent surge in cryo-EM instruments, demand for their use continues to outpace supply, and the high cost of instrument time further limits broader access to this technology. As a result, there is a pressing need for automated, reliable approaches that can efficiently collect high-quality datasets in cryo-EM. A key challenge lies in the uncertainty associated with sample quality and the unpredictable microscope conditions prior to data collection.

As the cryo-EM field has grown, it has attracted the attention of the mathematical and statistical communities. Naturally, the focus of mathematical, statistical, and machine learning research has been the fundamental inverse problem of obtaining 3D reconstructions from 2D projections, which is especially challenging in cryo-EM due to the very low signal-to-noise ratio. However, less attention has been given to processes before the reconstruction stage. To become robust and streamlined, cryo-EM requires a new framework that connects data collection with 3D reconstructions. Yet, to date, there is no formalism that enables efficient data collection nor are there formulations to connect uncertainty in 3D reconstructions with upstream data collection decisions.

### SUMMARY

The embodiments model the cryo-EM data collection process as a decision-making problem and optimize the sampling strategy accordingly. The aspects include a bandit optimization model that captures the unknown variations in data quality across regions within cryo-EM grids. In contrast to other bandit setups, the aspects incorporate random time costs with unknown distributions to represent the time spent on microscope operations. Within this framework, the aspects include an online learning algorithm that leverages streaming historical data to predict data quality in unvisited grid regions. Using the predicted data quality, the aspects schedule microscope operations accordingly, reducing unnecessary time costs. Through mathematical analysis, the aspects may efficiently maximize high-quality data acquisition over time, despite the presence of uncertainty. The aspects optimize cryo-EM data collection efficiency. Some aspects may employ a script-based optimization algorithm that is widely compatible with cryo-EM instruments (e.g., SerialEM scripts). Essentially, algorithm monitors and controls the microscope during cryo-EM data collection. The aspects may describe a general framework for utilizing online feedback in cryo-EM and a foundation for fully automated cryo-EM workflows.

Aspects may automate data collection in cryogenic electron microscopy (cryo-EM) by optimizing a sampling strategy. For example, aspects may identify, based on patch-level images taken by a cryo-EM instrument, a plurality of holes within a patch of a cryo-EM grid. Each identified hole may be a candidate data collection point. Aspects may predict an expected reward for each identified hole based on features extracted from the patch-level images. Aspects may determine, using stochastic approximation, a dynamically adjusted threshold quality score representing an estimated optimal time-average reward. Aspects may select holes from the identified plurality of holes based on the expected reward by minimizing an objective function that depends on the dynamically adjusted threshold quality score, wherein the dynamically adjusted threshold quality score may be based at least in part on observed rewards from the selected holes and microscope operation times.

Advantages will become more apparent to those of ordinary skill in the art from the following description of the preferred embodiments which have been shown and described by way of illustration. As will be realized, the present embodiments may be capable of other and different embodiments, as well as other and different aspects of those embodiments, and their details are capable of modification in various respects. Accordingly, the drawings and description are to be regarded as illustrative in nature and not as restrictive.

### BRIEF DESCRIPTION OF THE DRAWINGS

The figures described below depict various aspects of the system and methods disclosed herein. Each figure depicts an embodiment of a particular aspect of the disclosed system and methods, and each of the figures is intended to accord with a possible embodiment thereof.

There are shown in the drawings arrangements which are presently discussed, it being understood, however, that the present embodiments are not limited to the precise arrangements and instrumentalities shown, wherein:

FIG. 1 illustrates a typical cryo-EM data collection process.

FIG. 2 illustrates conventional techniques in human control of the cryo-EM data collection process.

FIG. 3A illustrates an exemplary flow diagram for uncertainty-aware cryo-EM data collection.

FIG. 3B illustrates an exemplary algorithm for a trained hole predictor module.

FIG. 3C illustrates an exemplary algorithm for an online-learning hole predictor module.

FIG. 3D illustrates an alternative exemplary algorithm for a trained hole predictor module using a generalized objective function.

FIG. 3E illustrates an alternative exemplary algorithm for an online-learning hole predictor module using a generalized objective function.

FIG. 4A illustrates an exemplary selection of a square from the grid.

FIG. 4B illustrates an exemplary selection of a patch within the squares of FIG. 4A.

FIG. 4C illustrates an exemplary identification of holes within the patches of FIG. 4B.

FIG. 4D illustrates an exemplary hole selection module.

FIG. 4E illustrates an exemplary full exposure that passes screening by the algorithm.

FIG. 4F illustrates an exemplary identification of particles from the full exposure of a hole.

FIG. 4G illustrates an alternative exemplary hole selection module using a generalized objective function.

FIG. 5 illustrates a comprehensive system architecture for uncertainty-aware cryo-EM data collection.

### DETAILED DESCRIPTION

The embodiments and their aspects described herein model the cryo-EM data collection process as a decision-making problem and optimize the sampling strategy accordingly. The reward definition in the decision-making problem may be flexible. For example, in some aspects, a high-quality micrograph may receive a reward of 1, whereas a low-quality micrograph may receive a reward of 0. In this context, the optimal time-average reward (Γ_{*}) may correspond to the maximum expected number of “good” images collected per unit time. If the reward for a micrograph is the number of particles that can be selected from it, the optimal time-average reward may be the maximum expected number of particles collected per unit of time.

Some aspects may include a contextual bandit optimization model designed for the single-particle cryo-EM data collection process. The model may account for the time costs associated with microscope operations. For example, when moving the microscope to collect data from a different location, a time delay may occur due to stage movement and microscope refocusing. The contextual bandit optimization model may include an optimal time-average reward (Γ_{*}) that can be achieved by any algorithm. The value of the reward may depend on the protein sample quality and microscope operations. Given a good protein sample and efficient microscope operation, the optimal time-average reward may be high.

Aspects may assume no prior knowledge about the protein sample quality and microscope condition before the cryo-EM data are collected. With no prior knowledge, aspects may formulate a learning problem and make decisions under uncertainty.

Aspects of the special contextual bandit model for single particle cryo-EM data collection may address the delays caused by microscope operation. The model may also estimate a time-average reward using stochastic approximation. Aspects may include a low-value alarm when the observed reward falls below a threshold, indicating wasted microscope time. Such a low-value alarm may signal a malfunction in the microscope system or poor protein sample quality (e.g., contaminated or degraded samples). Aspects may also include a learning algorithm that can actively learn to predict data quality in grids and schematically control the microscope to collect data. The learning algorithm may align with human intuition and offer strong, provable theoretical guarantees. Aspects including an online or computer network-enabled learning design may be generalizable to different tasks featured by new protein types, grid types, and microscope setups.

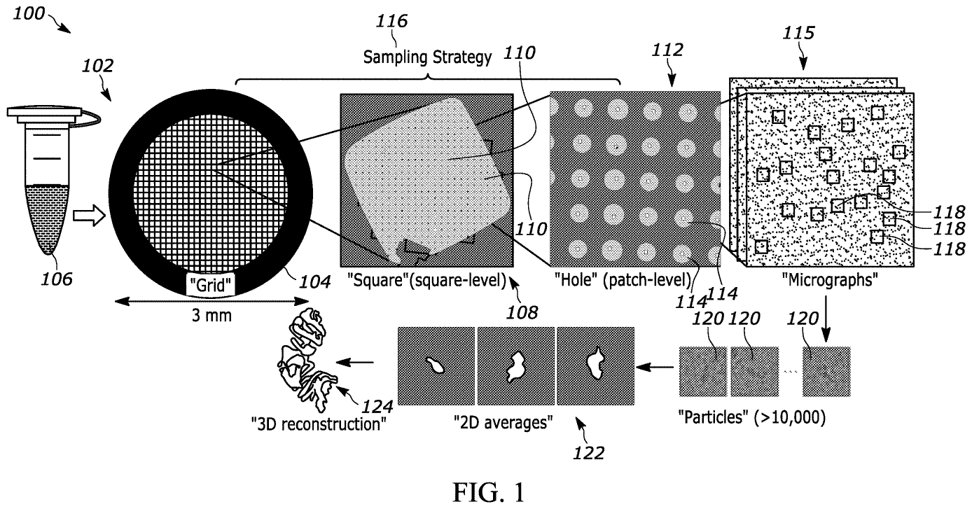

FIG. 1 may show a typical cryo-EM data collection process 100. At 102, a cryo-EM instrument may employ a grid 104 including a sample 106. A cryo-EM grid 102 may be used to image the sample 104. The cryo-EM grid 104 may be made of copper with a carbon film, gold with gold film, nickel-titanium alloy support film grids, or any other type of grid suitable for use by a cryo-EM instrument. Likewise, the cryo-EM grid 104 may be screened to ensure it contains a rich distribution of monodisperse particles supported by a thin layer of vitreous ice. At 108, the cryo-EM grid 104 may include a plurality of squares 110. Each square 110, as shown at 112, may include a plurality of holes 114. Elements 102, 108, and 112 may include a sampling strategy portion 116 of cryo-EM data process that may be optimized, as described herein. At 116, a plurality of micrographs 118 may be imaged by the instrument within each hole 114, with each micrograph 118 including particles 120 for imaging. Processing a large number of micrographs (e.g., >10,000), may result in 2D particle averages 122, which may then be used to create a three-dimensional reconstruction 124 of the particle. Good micrographs 118 may include particles that are well-separated and easily imaged by the instrument. Bad micrographs 118 may contain crystal ice and protein particle aggregation or may be empty.

In general, the cryo-EM sampling strategy process 116 shown by FIG. 1 may be a navigation problem in the sample space of the grid 104. Embodiments may find a trajectory of micrograph imaging over the grid 104 that maximizes the number of visited holes 114 with high-quality data over the shortest time.

Problems presented by the cryo-EM data collection process may include the difficulty of optimal path planning such as the orienteering problem (e.g., NP-hard), and the quality of data being unknown before taking exposures using the microscope. With no known rewards to guide the path planning beforehand, the entire sample grid 104 may be scanned at a low or medium magnification level (grid or patch level), but such examination requires hours of warmup time before micrographs 118 may be collected.

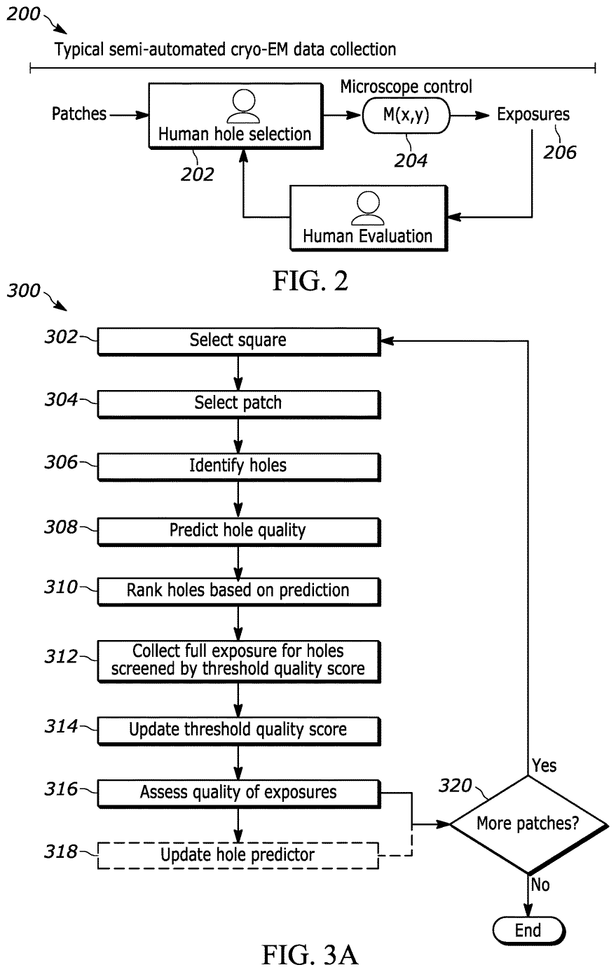

With reference to FIG. 2, human control of a cryo-EM instrument may compensate for some of the difficulties of the cryo-EM data collection process 200.

Human experimentalists typically do not intentionally select patches of holes 114 according to their location on the grid 102. Human experimentalists typically begin the sampling strategy process 116 by recording an ‘atlas’, which may map out the explorable areas throughout the grid 104. The atlas may be generated by recording several overlapping low-magnification images that may be stitched together to give a comprehensive view of the grid 104. Human users may identify the most promising areas of the grid from the grid atlas. Coordinates or other location information may be included in the atlas for the instrument to navigate to specific grid squares 110. After the user has identified squares of interest, a panoramic view of each square may be recorded in a similar way in which the atlas was acquired. In some aspects, a grid 104 may contain varying numbers of individual holes 114 that are suitable for micrographs 118, such as dozens to hundreds of holes depending on the grid configuration and sample preparation. Holes suitable for micrographs may include those containing particles that are well-separated (e.g., individual particles may be distinguished and picked for downstream processing) and supported by a layer of vitreous ice that permits electron transmission while maintaining particle integrity. Holes that are empty and lack sufficient particles for imaging, contain crystal ice or protein particle aggregation, or are overly dense such that particles overlap or cannot be individually resolved may be less suitable for data collection. With further reference to FIG. 2, at block 202, the human user may select holes according to medium magnification level (patch level) images. At block 204, the user may navigate the microscope to a position indicated by the atlas for full exposure 206. The instrument may then send micrographs at the highest magnification level to the user. An experienced microscopist may quickly find a correlation between patterns in patch-level hole images and the quality of the corresponding micrograph data.

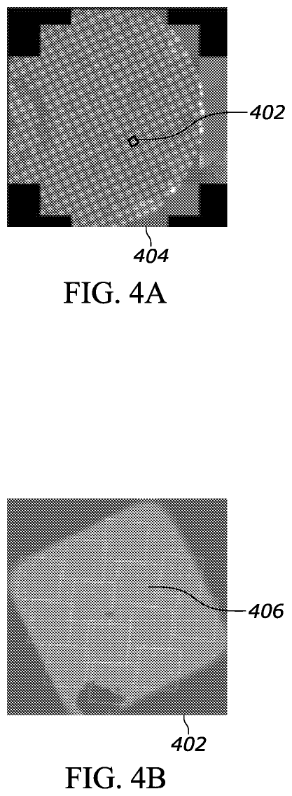

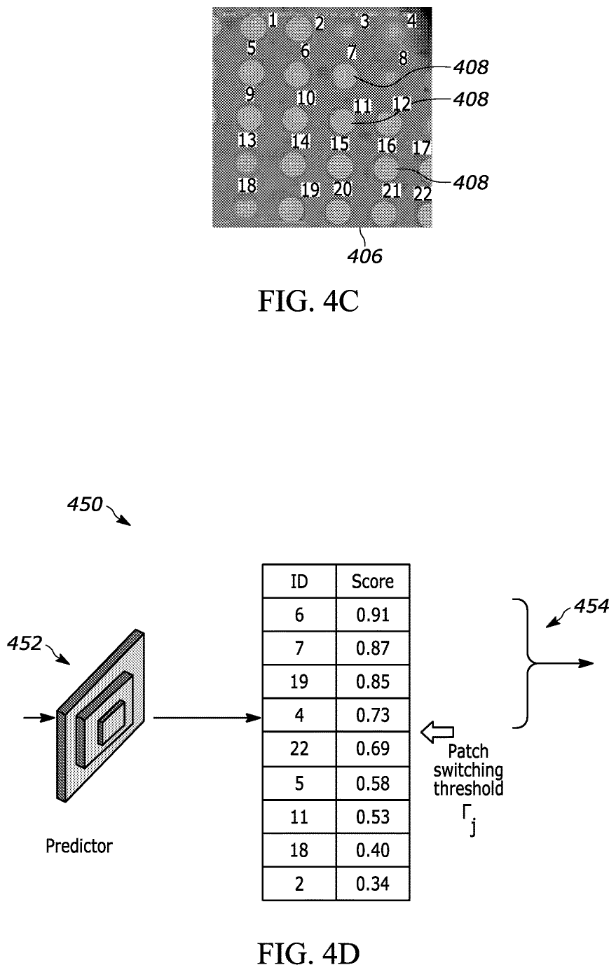

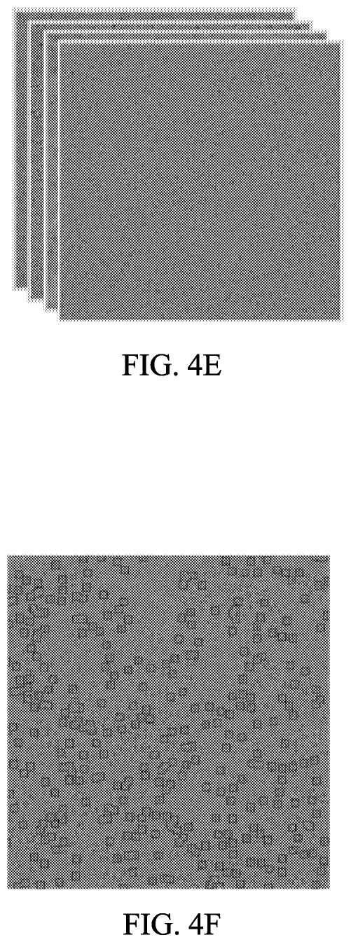

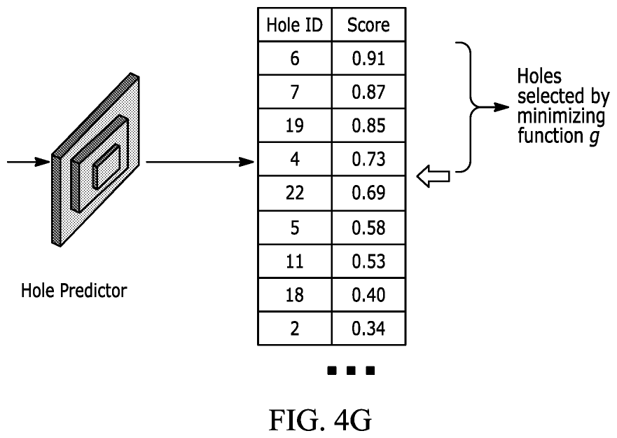

In a cryo-EM sampling strategy process 116, the data quality or “reward” of a selected hole 114 may only be known after the full exposure is made at the same hole. Thus, the user may only observe feedback as rewards or consequences for the action they have chosen, and they do not get to see the rewards for other actions that they could have taken. In machine learning, this type of decision-making and optimization is known as “bandit” feedback. In some embodiments, a trained hole predictor 452a (FIG. 4G) may employ machine learning techniques, utilizing bandit feedback to predict hole quality.

### Problem Formulation

Bandit feedback may be useful to formulate the problem within the context of cryo-EM data collection. The instrument may start cryo-EM data collection at t=0 and the instrument may request a patch of holes. Let the set [symbol] ⱼ={X_{j,1}, . . . , X_{j,N}_{ⱼ}} be the jth requested hole patch (decision set in contextual bandit literature), with each X_{j,i} representing the patch-level hole image of the ith hole in [symbol] ⱼ. The decision set may also be called context in bandit literature. Each hole patch comprises a group of holes configured for acquisition within a single beam-image shift group. The number of holes Nⱼ∈ [symbol] may be assumed to be a finite random variable since some holes 114 in the grid 102 are unusable. The corresponding “request time” (i.e., microscope operation time) for [symbol] ⱼ may be a random variable denoted by Sⱼ due to microscope operation (stage moving and refocusing). By selecting hole X_{j,i} from [symbol] ⱼ, the microscope may take a full exposure at the ith hole in [symbol] ⱼ and receive a random reward Y_{j,i} related to the quality of the collected micrograph. The reward definition may be flexible, e.g., {0, 1} reward for good and bad micrograph 118 or number of particles picked from the micrograph 118. Let expected reward of jth hole be [symbol] [Y_{j,i}]=ψ_{*}(X_{j,i}), where function (predictor) ψ, may be unknown. Following the standard realizability ASSUMPTION 1 for contextual bandit problems, the trained hole predictor 450 may be given a predictor class [symbol] , including, but not limited to, linear models, logistic regression models, neural network models, or other models sufficiently expressive to represent the underlying predictor function ψ.

Assumption 1 (Realizability) there Exists a Predictor ψ, ∈ [symbol] , and b>0 Such that for any Round j,

$$𝔼 [ {Y}_{j , i} ] = {ψ}_{*} ( {X}_{j , i} ) for all i ∈ \{ 1 , … , {N}_{j} \} .$$

The learner may select multiple holes Aⱼ⊆ [symbol] ⱼ from the hole patch [symbol] ⱼ. Since Aⱼ can be an arbitrary subset of [symbol] ⱼ, the action space becomes the power set of [symbol] ⱼ denoted by [symbol] ⱼi= [symbol] . For any Aⱼ∈ [symbol] ⱼ, let |Aⱼ| be the number of selected holes from hole patch [symbol] ⱼ. Each selection Aⱼ can be interpreted as an action, and the total time expended during the jth decision round can defined as Lⱼ(Aⱼ), where Lⱼ(·) may be determined according to the operational durations of the microscope. In some embodiments, each hole exposure is assumed to take a fixed duration Tₑₓₚ, so the total time spent may be expressed as:

$${L}_{j} ( {A}_{j} ) = {S}_{j} + {T}_{exp} \vert {A}_{j} \vert \qquad Specific embodiment 1$$

In other embodiments If |Aⱼ|>0, the microscope may perform additional operations, including stage movement and refocusing, which may incur a duration Tₘₒᵥ. In such cases, the total time expended may be represented as:

$$Specific embodiment 2$$

$${L}_{j} ( {A}_{j} ) = {S}_{j} + {T}_{mov} 1 \{ \vert {A}_{j} \vert > 0 , \} + {T}_{exp} \vert {A}_{j} \vert$$

Aspects may also include boundedness ASSUMPTION 2.

Assumption 2 (Boundedness) For any round j∈ [symbol] with hole set [symbol] ⱼ={X_{j,1}, . . . , X_{j,N}_{ⱼ}}
the expected reward ψ_{*}(X_{j,i})∈[−1,1] for all i∈{1, . . . , N};
the number of holes Nⱼ=| [symbol] |≤n for some n>0;
   the hole request time [symbol] >s for some s>0.

Some embodiments employ the preceding problem formulation to indicate an optimal time-average reward and describe one or more learning algorithms to maximize the accumulated reward in the context of cryo-EM data collection.

### Definition of Maximum Time-Average Reward

For each decision set of holes 114 ( [symbol] ), some embodiments may follow an algorithm to select a subset of holes from it. Specifically, an algorithm π may map the sampling history up to time t to a probability distribution over action space [symbol] ⱼ. Embodiments may also let Jₜ be the total number of decision sets that have been received until t. Aspects may also define an accumulated mean reward for an algorithm π at t, as EQUATION 1:

$${Q}^{π} ( t ) := 𝔼 [ {\sum }_{j = 1}^{Jt} {\sum }_{i ∈ {A}_{j}} {Y}_{j , i} ] = 𝔼 [ {\sum }_{j = 1}^{Jt} {\sum }_{x ∈ {A}_{j}} {ψ}_{*} ( x ) ] \qquad EQUATION 1$$

The accumulated mean reward may be a random variable with distribution determined by [symbol] and if. In aspects including an average-reward setting, the quality of an algorithm if may be evaluated by time-average reward while following π, as EQUATION 2:

$${Γ}^{π} := {lim}_{t \to ∞} sup \frac{1}{t} {Q}^{π} ( t ) \qquad EQUATION 2$$

Rewards, hole request time (i.e., microscope operation time), and costs may all be bounded in some aspects, so Γ^{π} may be bounded for all π. For the problem, the optimal time-average reward that can be achieved by any algorithm may be defined as EQUATION 3.

$${Γ}_{*} := {sup}_{π} {Γ}^{π} \qquad EQUATION 3$$

### Property of Maximum Time-Average Reward

In the bandit optimization model for cryo-EM data collection, as introduced above in some aspects it is assumed that

$${\{ ( {X}_{j ,} {L}_{j} ) \}}_{j = 1}^{∞}$$

forms IID sequence with distribution [symbol] . Let ( [symbol] ,L) be a random sample from [symbol] and

$$μ = {\{ {μ}_{i} \}}_{i = 1}^{N} ,$$

where μᵢ=ψ_{*}( [symbol] ᵢ) for each i=1, . . . , N and N=| [symbol] |. Each selection of holes A⊆ [symbol] may be associated with a duration L(A). Proposition 1 (Optimal Time-Average Reward) The optimal time-average reward Γ_{*} may be characterized as the value of f satisfying

$$𝔼 [ {min}_{A ⊆ X} g ( Γ , L , μ , A ) ] = 0 ,$$

where g(·) is defined as

$$g ( Γ , L , μ , A ) = L ( A ) Γ - {\sum }_{i ∈ A} {μ}_{i} \qquad EQUATION 4$$

According to proposition 1, the value of Γ_{*} may depend on the distribution of μ and latency function L(·), which may capture characteristics of the overall grid sample quality, microscope operation times, or other factors affecting data collection. The function g(Γ, L, μ, A) may measure a gap between rewards received at a target rate F and a mean reward actually obtained from action A over a time duration L(A). This result may indicate that, to achieve an optimal time-average reward Γ_{*}, hole selection 114 (FIG. 1) may be performed by minimizing an objective function g(Γ, L, μ, A). k₁ . . . k_{L} may be a sequence such that μₖ_{₁}≥μₖ_{₂}, . . . ≥μₖ_{_{L}}, Γ may be a real value, and the number of values in μ no less than ΓTₑₓₚ may be n(Γ). In the setup of Specific embodiment 1, minimizing g(Γ_{*}, L, μ, A) may be achieved by selecting holes whose expected reward is no less than Γ_{*}Tₑₓₚ, i.e.,

$$\text{?} g ( {Γ}_{*} , L , μ , A ) = h ( {Γ}_{*} , S , μ ) = [ S + n ( {Γ}_{*} ) {T}_{exp} ] {Γ}_{*} - {\sum }_{i = 1}^{n ( {Γ}_{*} )} {μ}_{{k}_{i}} \qquad EQUATION 5$$

In some aspects, [symbol] ( [symbol] g(Γ_{*}, L, μ, A)=0 may permit construction of an estimator for Γ_{*}. Stochastic approximation is a standard method for finding the root of an unknown real-valued function when only noise-corrupted measurements are available.

### Automated Data Collection

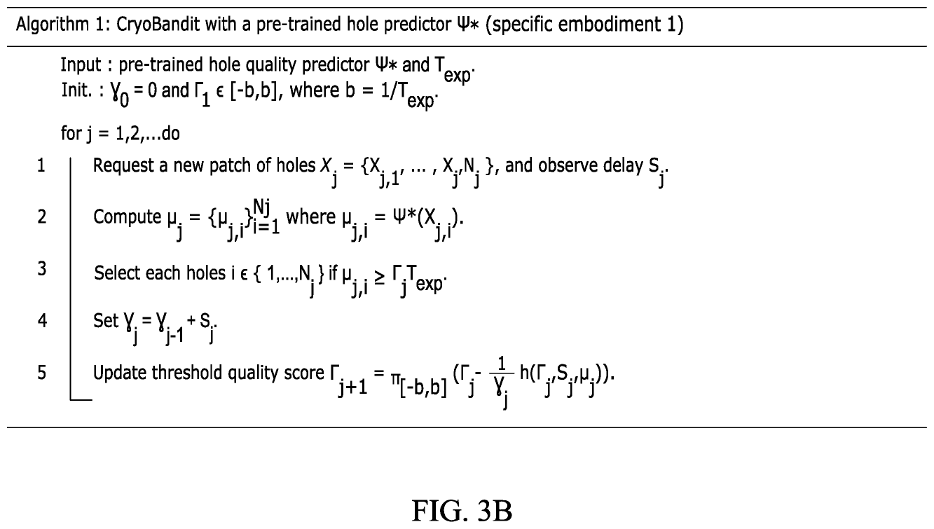

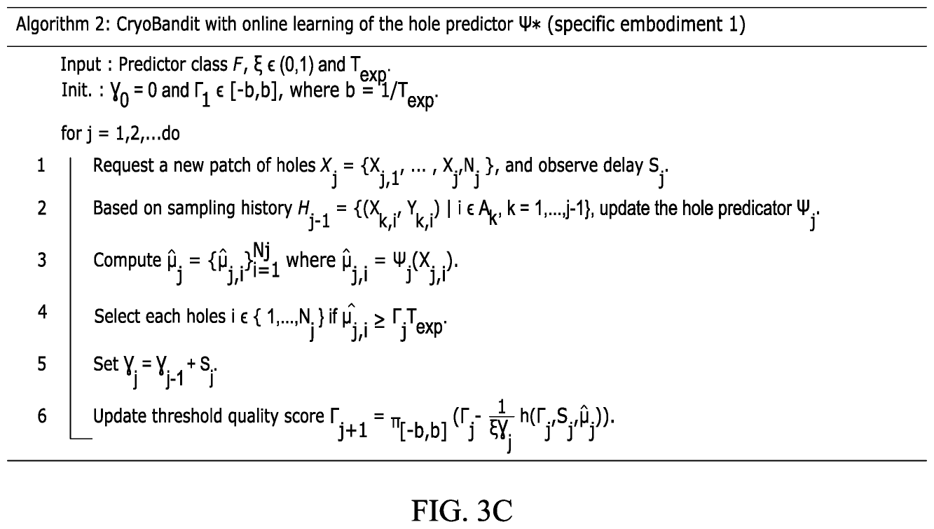

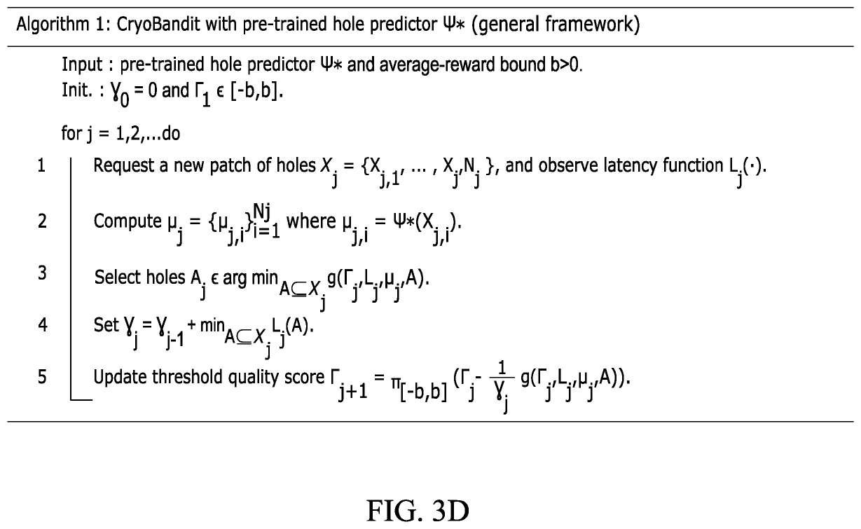

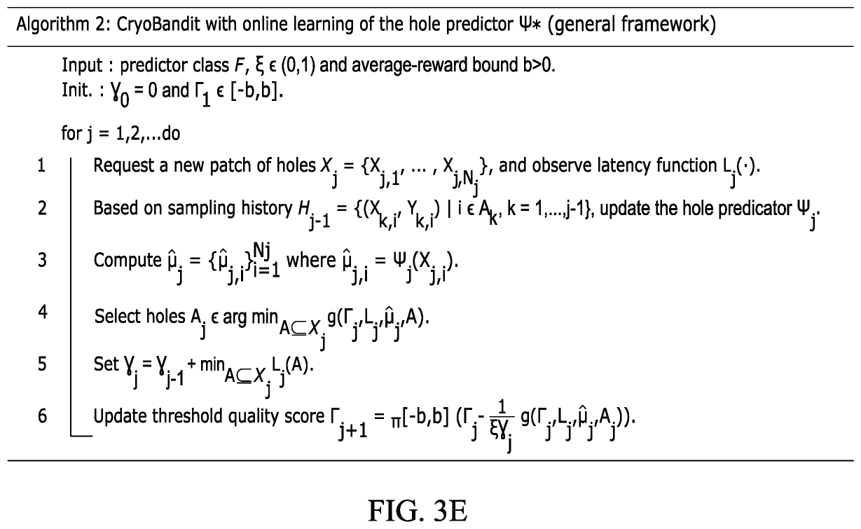

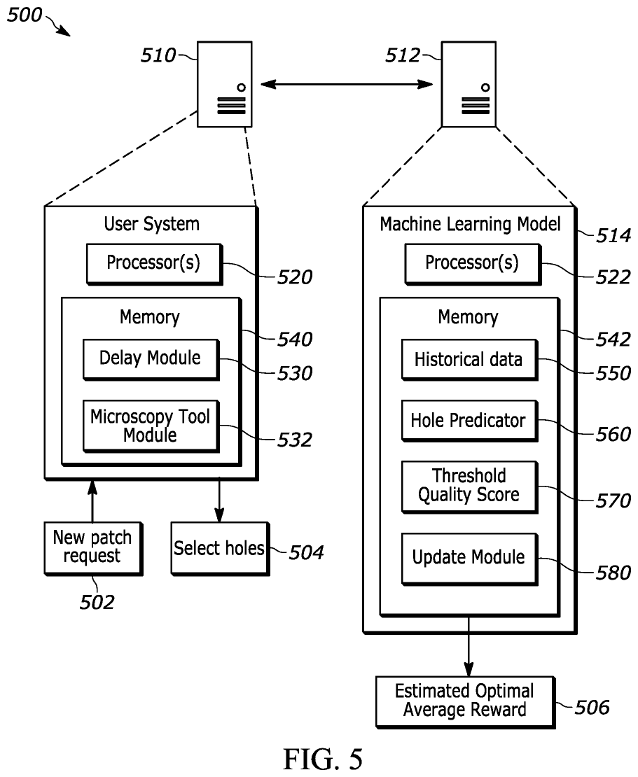

In some aspects, for a random sample of holes 114, expressed [symbol] ⱼ, an algorithm may select holes 114 for data collection by minimizing an objective function g(Γ_{*}, L, μ, A). In further aspects, e.g., in a typical cryo-EM data collection process where Γ_{*} may be unknown and ψ_{*} may not be given, uncertainty introduced by these missing elements may be uncoupled from the data collection process. For example, ψ_{*} may be a trained hole predictor module (e.g., 560, FIG. 5) including computer-executable instructions for predicting which holes 114 within the grid 102 are best for data collection. In some aspects, the trained hole predictor module 560 may include computer-executable instructions as in ALGORITHM 1 (FIG. 3B/FIG. 3D). As used herein, stochastic approximation may refer to any iterative estimation technique configured to determine a root or fixed point of a function based on noisy, partial, or sequential observations, and is not limited to any particular formulation. In other aspects, the requirement for predictor ψ_{*} may be relaxed and automated data collection may rely on an online learning module (e.g., 560, FIG. 5) for the hole predictor ψ_{*} and computer-executable instructions as in ALGORITHM 2 (FIG. 3C/FIG. 3E). In certain aspects, it may be desirable for the hole predictor to incorporate exploration when estimating expected rewards for candidate holes. Exploration enables the method to sample holes whose outcomes are uncertain, rather than exclusively selecting holes that currently appear to have high estimated rewards. By sampling a diverse set of holes, the predictor may obtain a more accurate and robust estimate of expected rewards across variations in hole properties.

The methods described herein may also assist in the human operation of a cryo-EM instrument by recommending which of the holes 408 should be selected for collecting a full micrograph 118 (FIG. 1). In certain aspects, the systems and methods may monitor the sampling strategy 116 and data collection process 100 through computation of an time-average reward metric Γⱼ. If Γⱼ falls below a threshold value, this may indicate a malfunction in the cryo-EM instrument or insufficient protein sample quality. Accordingly, the systems and methods described herein may facilitate detection of instrument performance degradation or sample quality issues. In some aspects, within the bandit optimization model, the disclosed methods may achieve the optimal time-average reward F, as the time horizon T approaches infinity, while also providing near-optimal performance over finite time horizons.

### Automated Data Collection Systems

In some aspects, a method 300 (FIG. 3A) may control a cryo-EM instrument for automatically collecting micrographs by implementing the sampling strategy 116 described in FIGS. 3B-E. The method 300 may include a plurality of “function blocks” or “blocks” comprising processor-executable instructions for performing one or more functionalities described herein. Each block may have defined inputs and outputs and may perform a particular operation or set of operations based on the inputs it receives. These blocks of method 300 may be stored and executed, at least in part, using an exemplary computing environment 500, as described herein.

At block 302, aspects may be configured to select a square 402 (FIG. 4A) from the grid 404. The selection may be random, based on human input, or based on an automated assessment derived from a low-magnification square-level 108 image of the square 402. At block 304, aspects may be configured to select a patch 406 within the square 402 selected at block 302. The patch may be selected randomly, based on human input, or based on an automated assessment derived from a medium-magnification patch-level 114 image of the hole patch 406. At block 306, aspects may be configured to identify holes 408 within the selected patch 406 (FIG. 4C). In some aspects, the holes may be identified based on human input or by a computer vision algorithm. The resulting patch-level images may be used to estimate rewards corresponding to micrograph quality at each hole. At block 308, some aspects may include processor-executable instructions to optionally employ a hole selection module 450 (FIG. 4D) to predict hole quality. The hole selection module 450 includes a hole predictor 452 and estimator Γⱼ computed with stochastic approximation, as described herein, to filter out holes 408 that should not be selected by comparing against ΓⱼTₑₓₚ (454). At block 310, some aspects may include processor-executable instructions to rank the holes 408 based on their predicted data quality. In some aspects, they are ranked by the process outlined in ALGORITHM 2 of FIG. 3C. At block 312, some aspects may include processor-executable instructions to collect full exposure for a hole 408 if the predicted data quality passes screening based on the threshold quality score. FIG. 4E illustrates an exemplary full exposure for such holes 408. At block 314, some aspects may include processor-executable instructions to assess the quality of exposures to update the system based on the difference between a holes 408 predicted data quality and observed data quality. At block 316, some aspects may include processor-executable instructions to update the threshold quality score based on the observed data quality and/or the time delay required to refocus the microscope. FIG. 4F illustrates an exemplary assessment of micrograph quality, wherein particles 120 may be identified from each collected micrograph 118 for downstream processing. At block 318, some aspects may include processor-executable instructions to update the hole predictor based on the observed data quality and/or the time delay required to refocus the microscope. At block 320, some aspects may include processor-executable instructions to decide whether to select more patches and return to block 304, or end at block 322.

With reference to FIG. 3B, F₁ may be the estimate of Γ_{*} upon receiving the jth hole patch. Once an aspect receives the decision set of patch-level holes [symbol] ⱼ, and with hole predictor Ψ_{*} given, the expected rewards for all holes in [symbol] ⱼ may be computed as represented by

$${μ}_{j} = {\{ {μ}_{j , i} \}}_{i = 1}^{{N}_{j}} \cdot .$$

In some aspects, ALGORITHM 1 (FIG. 3B) may select all holes 408 if their predicted rewards in μⱼ is no less than ΓⱼTₑₓₚ (i.e., Line 3 of ALGORITHM 1 in FIG. 3B). In some aspects, using ASSUMPTION 2 above and that the value of ψ_{*} is in [−1,1], resulting in |Γ_{*}|≤b where b=1/Tₑₓₚ. The estimator of Γ_{*} may be initialized by setting Γ₁∈[−b, b]. Aspects may also iteratively apply a stochastic approximation at Line 5 of ALGORITHM 1 in FIG. 3B,

$${Γ}_{j} - \frac{1}{{γ}_{j}} h ( {Γ}_{j} , {S}_{j} , {μ}_{j} )$$

where h may be defined in EQUATION 5, above, and the value may be projected back to [−b, b] using the operator π_{[-b,b]}.

With reference to FIG. 3C, the predictor ψ_{*} may not be given and may require the learning of a predictor in predictor class [symbol] from noisy observations of the patch-level holes (e.g., as described above in relation to blocks 304 and 306). As data is collected using method 300, the sampling history may accumulate observations of hole contexts and corresponding micrograph quality rewards to round j−1, which may be represented as [symbol] ⱼ₋₁={(X_{k,i}, Y_{k,i})|i∈Aₖ, 1, . . . , j−1}. In some aspects, ALGORITHM 2 shown in FIG. 3C may extend ALGORITHM 1 of FIG. 3B to address learning a predictor in [symbol] from the patch-level holes images in blocks 304 and 306. For example, as data is collected in blocks 304 and 306, aspects may construct an estimator ψⱼ∈ [symbol] by learning ψ_{*} from [symbol] ⱼ₋₁. The hole predictor may compute the estimated expected rewards for all holes in [symbol] ⱼ as

$${\hat{μ}}_{j} = {\{ {\hat{μ}}_{j , i} \}}_{i = 1}^{{N}_{j}}$$

where \hat{μ}_{j,i}=ψⱼ(X_{j,i}) for each i∈{1, . . . , Nⱼ}. The parameter ξ∈(0,1) may be user-defined to control the learning rate of the stochastic approximation. Replacing the expected rewards μⱼ indicated in ALGORITHM 1 of FIG. 3B with the predicted rewards \hat{μ}ⱼ, and applying a parameter ξ∈(0,1) may result in ALGORITHM 2 of FIG. 3C.

The construction of ψⱼ and computation of \hat{μ}_{j,i} may employ a standard estimator, such as a least-squares estimator, or any uncertainty-aware method from the bandit optimization literature. In some aspects, the uncertainty-aware method may include, but is not limited to, Upper Confidence Bound, Thompson sampling. In certain aspects, it may be desirable for the hole predictor to incorporate exploration when estimating expected rewards for candidate holes. Exploration enables the method to sample holes whose outcomes are uncertain, rather than exclusively selecting holes that currently appear to have high estimated rewards. By sampling a diverse set of holes, the predictor may obtain a more accurate and robust estimate of expected rewards across variations in hole properties.

In some aspects, the hole selection described above with reference to ALGORITHMS 1 and 2 (FIGS. 3B-C) may alternatively be expressed using a generalized objective function when the specific embodiment 1 does not apply. According to proposition 1, the generalized objective function g(ψ_{*}, L, μ, A) defined in EQUATION 4 above may measure a gap between rewards received at a target rate Γ and a mean reward actually obtained from action A over a time duration L(A). In some aspects, [symbol] [ [symbol] g(Γ_{*}, L, μ, A)]=0 may permit construction of Γⱼ in each decision round j as the estimator for Γ_{*}. The hole selection Aⱼ in each decision round is done by minimizing objective function g.

In some aspects, with reference to FIG. 3D, ALGORITHM 1 may alternatively receive as input a trained hole quality predictor ψ_{*} and a reward bound b>0. The threshold quality score may be initialized by setting Γ₁∈[−b, b] and learning rate parameter may be initialized by setting γ₀=0. For each round j, the algorithm may request a new patch of holes [symbol] ={X_{j,1}, . . . , X_{j,N}_{ⱼ}} and observe a latency function Lⱼ(·). With reference to FIG. 3D, Γⱼ may represent an estimate of Γ_{*} upon receiving the jth hole patch. Once an aspect receives the decision set of patch-level holes [symbol] ⱼ, and given the trained hole predictor ψ_{*}, the expected rewards for all holes in [symbol] ⱼ may be computed as

$${μ}_{j} = {\{ {μ}_{j , i} \}}_{i = 1}^{{N}_{j}} .$$

In some aspects, ALGORITHM 1 (FIG. 3D) may select holes 408 by minimizing g(Γⱼ, L, μ, A) (i.e., Line 3 of ALGORITHM 1 in FIG. 3D), using Γⱼ in place of Γ_{*}. The estimator Γ_{*} may be initialized by setting Γ₁∈[−b, b]. In some aspects, a stochastic approximation may be configured to be iteratively applied at Line 5 of ALGORITHM 1 in FIG. 3D, wherein g(·) may be defined in EQUATION 4 above. The updated value may be configured to be projected back onto [−b, b] using the operator Π_{[-b,b]}. By employing an increasing γⱼ, the learning rate may be configured to decrease as the sampling history accumulates.

In some aspects, with reference to FIG. 3E, ALGORITHM 2 may alternatively receive as input a predictor class [symbol] , a reward bound b, and a scaling parameter ξ∈(0,1). The threshold quality score may be initialized by setting Γ₁∈[−b, b] and learning rate parameter may be initialized by setting γ₀=0. In some aspects, ALGORITHM 2 shown in FIG. 3E may extend ALGORITHM 1 of FIG. 3D and may operate without requiring the hole predictor ψ_{*} to be provided. A predictor class [symbol] , sufficiently expressive to contain the function ψ_{*} (see ASSUMPTION 1), may be provided. In such aspects, learning of p, may be performed by evaluating the micrograph qualities from the selected holes, as described above with reference to blocks 312, 314, and 318. In certain aspects, it may be desirable for the hole predictor to incorporate exploration when estimating expected rewards for candidate holes. Exploration enables the method to sample holes whose outcomes are uncertain, rather than exclusively selecting holes that currently appear to have high estimated rewards. By sampling a diverse set of holes, the predictor may obtain a more accurate and robust estimate of expected rewards across variations in hole properties.

With reference to FIG. 3E, for each round j, the algorithm may request a new patch of holes [symbol] ⱼ={X_{j,1}, . . . , X_{j,N}_{ⱼ}} and observe a latency function Lⱼ(·). As data is collected using method 300, the sampling history may accumulate observations of hole contexts and corresponding micrograph quality rewards to round j−1, which may be represented as [symbol] ⱼ₋₁={(X_{k,i},Y_{k,i})|i∈Aₖ, k=1, . . . , j−1}. In a regression context, each Y_{k,i} may be viewed as a noisy observation of the underlying expected reward ψ_{*}(X_{k,i}). By learning ψ_{*} from [symbol] ⱼ₋₁, the hole predictor ψⱼ at jth round may compute the estimated expected rewards for all holes in [symbol] ⱼ as

$${\hat{μ}}_{j} = {\{ {\hat{μ}}_{j , i} \}}_{i = 1}^{{N}_{j}} .$$

The computation of \hat{μ}_{j,i} may employ any uncertainty-aware method from the bandit optimization literature, including, but not limited to, Upper Confidence Bound, Thompson sampling, or least-squares estimation, which may be applied greedily without explicitly accounting for exploration. The parameter ξ∈(0,1) may be user-defined to control the learning rate of the stochastic approximation. The update rule for the learning rate parameter γⱼ may, for example, be implemented at Line 5 of ALGORITHM 2 in FIG. 3E, without limitation to this particular formulation. Holes Aⱼ may be selected by minimizing the objective function g(Γⱼ, Lⱼ, \hat{μ}ⱼ, A) over subsets A⊆ [symbol] ⱼ. The learning rate parameter γⱼ may be updated as γⱼ=γⱼ₋₁+ [symbol] Lⱼ(A) The threshold quality score may then be updated as

$${Τ}_{j + 1} = {\prod }_{[ - b , b ]} ( {Γ}_{j} - \frac{1}{{ξγ}_{j}} g ( {Γ}_{j} , {L}_{j} , {\hat{μ}}_{j} , A ) )$$

where the value may be projected back to [−b, b] using the operator Π_{[-b,b]}.

With reference to FIG. 4G, in some aspects, a hole selection module 450a may alternatively select holes by minimizing the objective function g, as described above with reference to FIGS. 3D and 3E. The hole selection module 450a employs a hole quality predictor 452a and an estimator of Γ_{*}, as described herein. Minimizing the objective function g corresponds to selecting holes according to their predicted rewards with the screening standard set by threshold quality score Γⱼ.

The present disclosure includes improvements in computer functionality or in improvements to other technologies at least because the claims recite that, e.g., the computing system predicts an expected reward for each identified hole based on features extracted from patch-level images, determines a dynamically adjusted threshold quality score representing an estimated optimal time-average reward using stochastic approximation, and selects holes whose expected rewards meet the screening standard set by the dynamically adjusted threshold quality score. That is, the present disclosure describes improvements in the functioning of the computer itself or any other technology or technical field because the disclosed system dynamically computes and updates a threshold quality score using stochastic approximation based on observed rewards and microscope operation times, enabling automated real-time optimization of cryo-EM data collection without requiring human intervention to evaluate each candidate hole. The system further improves data collection efficiency by filtering out low-quality holes and scheduling microscope operation before full exposure, thereby reducing wasted microscope time and computational resources that would otherwise be spent processing poor-quality micrographs. This improves over the prior art at least because the disclosed system transforms raw patch-level image data into actionable hole selection decisions through a feedback-driven computational pipeline that iteratively refines its prediction accuracy based on observed micrograph quality outcomes. Unlike conventional systems that process each hole selection independently without learning from prior results, the disclosed system maintains and updates a statistically grounded screening parameter through stochastic approximation, enabling the computing system to automatically calibrate its selection criteria to the specific characteristics of each cryo-EM grid and microscope configuration without requiring manual parameter tuning or human evaluation of intermediate results.

The present disclosure includes specific features other than what is well-understood, routine, conventional activity in the field, or adding unconventional steps that confine the claim to a particular useful application, e.g., determining, using stochastic approximation, a dynamically adjusted threshold quality score representing an estimated optimal time-average reward, wherein the dynamically adjusted threshold quality score is based at least in part on observed rewards from the selected holes and microscope operation times. Conventional cryo-EM data collection systems rely on human microscopists to manually evaluate patch-level images and select holes for data collection based on subjective visual assessment. The disclosed systems and methods provide an unconventional technical solution by applying stochastic approximation techniques to dynamically compute and update a threshold quality score that adapts in real-time based on observed micrograph rewards and microscope operation delays, thereby automating the hole selection process in a manner that was not previously achievable through conventional approaches. Additionally, the disclosed systems and methods include predicting an expected reward for each identified hole based on features extracted from patch-level images, and selecting holes whose expected rewards meet a screening standard set by a dynamically adjusted threshold quality score, which represents an unconventional application of contextual bandit optimization models to the cryo-EM data collection domain that accounts for the unique time costs associated with microscope operations such as stage movement and refocusing delays.

FIG. 5 depicts an exemplary computing environment 500 for implementing techniques for cryo-EM data collection, and more particularly, for techniques using an uncertainty-aware method for single particle cryo-EM data collection using online feedback, according to some embodiments. The computing environment 500 includes a user system 510 and a server 512. The computing environment 500 illustrated in FIG. 5 may include both hardware and software applications, as well as various data communications channels for communicating data between the various hardware and software components, as is described below. The computing environment 500 illustrated in FIG. 5 further includes various components and channels for communication and data flow, as is described below.

The user system 510 may, for example, include a desktop computer, laptop computer, smartphone, tablet, wearable computing device, and/or other client computing device(s). The user system 510 contains processor(s) 520 a memory 540, which may further include a delay module 530 and microscopy tool module 532. In some embodiments, the user system 510 includes storage capabilities for various data types that are utilized in or during operation. The memory 540 of the user system 510 may include one or more forms of volatile and/or non-volatile, fixed and/or removable memory, such as read-only memory (ROM), electronic programmable read-only memory (EPROM), random access memory (RAM), erasable electronic programmable read-only memory (EEPROM), and/or other hard drives, flash memory, MicroSD cards, and others. In some embodiments, the memory 540 of the user system 510 may also store a web browser via which a user can access a service provided by the organization that owns the user system 510. The memory 540 of the user system and/or the memory 542 of the server 512 may store one or more of the blocks described in relation to FIG. 3A, modules (e.g., delay module 530, microscopy tool module 532, historical data 550, hole predictor module 560, threshold quality score module 570, update module 580, etc.) and associated processor-executable instructions (e.g., function blocks of the method 300) as well as the algorithms and equations described herein for execution on one or more of the processors 520, 522. In some embodiments, the delay module 530 may calculate the operating delay associated with moving the microscope to a different hole 114 or patch of holes 114. The delay is then incorporated into the dynamically adjusted threshold quality score 570. The microscopy tool module may operate the microscopy tool to move and evaluate holes 114. In some embodiments, the user system 510 may receive a new patch request 502 and further may determine to select holes 504.

The server 512 includes a machine learning module 514 (e.g., hole predictor 450, etc) comprised of processor(s) 522 and a memory 542. The memory 542 of the machine learning module 514 may include historical data 550, a hole predictor 560, a threshold quality score 570, and an update module 580. In some embodiments, the server 512 uses the hole predictor 560 trained by historical data 550. The estimated optimal time-average reward 506 may predict the quality of micrograph data collectible from each hole. In even further embodiments, the threshold quality score is a dynamically adjusted threshold value that determines whether the microscopy tool should continue to probe the current hole 114 or patch of holes 114, or to move to a different hole or patch of holes 114. In even further embodiments, the update module 580 updates the hole predictor 560 and threshold quality score 570 using the latest observations from the historical data. The machine learning module 514 may include computer-executable instructions as in ALGORITHM 1 (FIG. 3B/FIG. 3D) or computer-executable instructions as in ALGORITHM 2 (FIG. 3C/FIG. 3E).

In some embodiments, the server 512 may be implemented as cloud-based servers, such as a cloud-based computing platform. For example, the server 512 may be any one or more cloud-based platform(s) such as MICROSOFT AZURE, AMAZON AWS, or the like. Either or both user system 510 and server 512 can further include a user interface, for example to display alerts or other indications as described later herein. The user interfaces may be provided in whole or in part on a display monitor (e.g., LCD screen, touch screen, or any other type of display) and can incorporate an integrated or separate sound system. In some embodiments, the user interface may provide one or more visual representations for monitoring the automated data collection process. For example, the user interface may display a representation of the selected holes within the cryo-EM grid, including indications of which holes have been selected for data collection, and which have been skipped. In some aspects, the user interface may further display a collected micrograph data quality assessment, such as a quality score or classification associated with each collected micrograph. In some aspects, the user interface may also display a current value of the dynamically adjusted threshold quality score, enabling a user to monitor the progression of the data collection optimization in real time. In certain embodiments, the user interface may provide alerts or notifications when the threshold quality score falls below a predetermined value, indicating potential issues with the cryo-EM instrument or protein sample quality.

### ADDITIONAL CONSIDERATIONS

The following considerations also apply to the foregoing discussion. Throughout this specification, plural instances may implement operations or structures described as a single instance. Although individual operations of one or more methods are illustrated and described as separate operations, one or more of the individual operations may be performed concurrently, and nothing requires that the operations be performed in the order illustrated. These and other variations, modifications, additions, and improvements fall within the scope of the subject matter herein.

It should also be understood that, unless a term is expressly defined in this patent using the sentence “As used herein, the term” “is hereby defined to mean . . . ” or a similar sentence, there is no intent to limit the meaning of that term, either expressly or by implication, beyond its plain or ordinary meaning, and such term should not be interpreted to be limited in scope based on any statement made in any section of this patent other than the language of the claims. To the extent that any term recited in the claims at the end of this patent is referred to in this patent in a manner consistent with a single meaning, that is done for sake of clarity only so as to not confuse the reader, and it is not intended that such claim term be limited, by implication or otherwise, to that single meaning. Finally, unless a claim element is defined by reciting the word “means” and a function without the recital of any structure, it is not intended that the scope of any claim element be interpreted based on the application of 35 U.S.C. § 112f.

Unless specifically stated otherwise, discussions herein using words such as “processing,” “computing,” “calculating,” “determining,” “presenting,” “displaying,” or the like may refer to actions or processes of a machine e.g., a computer that manipulates or transforms data represented as physical e.g., electronic, magnetic, or optical quantities within one or more memories e.g., volatile memory, non-volatile memory, or a combination thereof, registers, or other machine components that receive, store, transmit, or display information.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true or present and B is false or not present, A is false or not present and B is true or present, and both A and B are true or present.

In addition, use of “a” or “an” is employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for implementing the concepts disclosed herein, through the principles disclosed herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

The patent claims at the end of this patent application are not intended to be construed under 35 U.S.C. § 112(f) unless traditional means-plus-function language is expressly recited, such as “means for” or “step for” language being explicitly recited in the claim(s). The systems and methods described herein are directed to an improvement to computer functionality and improve the functioning of conventional computers.

What is claimed is:

1. A computing system for automated data collection in cryogenic electron microscopy (cryo-EM), the computing system comprising:
a processor; and
a memory having stored thereon computer-executable instructions that, when executed by the processor, cause the computing system to:
identify, based on patch-level images taken by a cryo-EM instrument, a plurality of holes within a patch of a cryo-EM grid, wherein each identified hole is a candidate data collection point;
estimate an expected reward for each identified hole based on the patch-level images;
determine, using stochastic approximation, a dynamically adjusted threshold quality score representing an estimated optimal time-average reward; and
select holes from the identified plurality of holes based on the expected reward by minimizing an objective function that depends on the dynamically adjusted threshold quality score, wherein the dynamically adjusted threshold quality score is based at least in part on observed rewards from the selected holes and microscope operation times.

2. The computing system of claim 1, wherein the computer-executable instructions further cause the computing system to:
determine the microscope operation times including a delay required to refocus the cryo-EM instrument;
adjust the dynamically adjusted threshold quality score; and
update a hole predictor based on an observed reward for each hole and the delay.

3. The computing system of claim 2, wherein the hole predictor includes a machine learning model configured to predict micrograph data quality based on patterns in patch-level hole images, and trained using streaming data acquired during cryo-EM data collection.

4. The computing system of claim 2, wherein the computer-executable instructions further cause the computing system to:
select a different plurality of holes within the patch of the cryo-EM grid based on the dynamically adjusted threshold quality score and the observed reward for each hole.

5. The computing system of claim 1, wherein the computer-executable instructions to estimate the expected reward for each identified hole based on the patch-level images include instructions to determine one or more of:
a maximum expected number of micrographs collected per unit time, or
a maximum expected number of particles within each micrograph collected per unit of time,
wherein the micrographs meet the dynamically adjusted threshold quality score collected per unit time.

6. The computing system of claim 1, wherein the computer-executable instructions further cause the computing system to:
provide a user interface including one or more visual representations of one or more of: 1) the selected holes, 2) a collected micrograph data quality assessment, or 3) a current value of the dynamically adjusted threshold quality score.

7. The computing system of claim 1, further comprising computer-executable instructions that, when executed by the processor, cause the computing system to:
dynamically rank the selected holes from the identified plurality of holes by one or more of the estimated expected reward, an Upper Confidence Bound, or Thompson sampling.

8. A computer implemented method for automated data collection in cryogenic electron microscopy (cryo-EM), the method comprising:
identifying, by one or more processors and based on patch-level images taken by a cryo-EM instrument, a plurality of holes within a patch of a cryo-EM grid, wherein each identified hole is a candidate data collection point;
estimating, by the one or more processors, an expected reward for each identified hole based on the patch-level images;
determining, by the one or more processors and using stochastic approximation, a dynamically adjusted threshold quality score representing an estimated optimal time-average reward; and
selecting, by the one or more processors, holes from the identified plurality of holes based on the expected reward by minimizing an objective function that depends on the dynamically adjusted threshold quality score, wherein the dynamically adjusted threshold quality score is based at least in part on observed rewards from the selected holes and microscope operation times.

9. The computer implemented method of claim 8, further comprising:
determining, by the one or more processors, the microscope operation times including a delay required to refocus the cryo-EM instrument;
adjusting, by the one or more processors, the dynamically adjusted threshold quality score; and
updating, by the one or more processors, a hole predictor based on an observed reward for each hole and the delay.

10. The computer implemented method of claim 9, wherein the hole predictor includes a machine learning model configured to predict micrograph data quality based on patterns in patch-level hole images, and trained using streaming data acquired during cryo-EM data collection.

11. The computer implemented method of claim 9, further comprising:
selecting, by the one or more processors, a different plurality of holes within the patch of the cryo-EM grid based on the dynamically adjusted threshold quality score and the observed reward for each hole.

12. The computer implemented method of claim 8, wherein estimating, by the one or more processors, the expected reward for each identified hole based on the patch-level images includes one or more of:
determining, by the one or more processors, a maximum expected number of micrographs collected per unit time, or
determining, by the one or more processors, a maximum expected number of particles within each micrograph collected per unit of time,
wherein the micrographs meet the dynamically adjusted threshold quality score collected per unit time.

13. The computer implemented method of claim 8, further comprising:
providing, by the one or more processors, a user interface including one or more visual representations of one or more of: 1) the selected holes, 2) a collected micrograph data quality assessment, or 3) a current value of the dynamically adjusted threshold quality score.

14. The computer implemented method of claim 8, further comprising:
dynamically ranking, by the one or more processors, the selected holes from the identified plurality of holes by one or more of the estimated expected reward, an Upper Confidence Bound, or Thompson sampling.

15. A non-transitory computer-readable medium having stored thereon computer-executable instructions that, when executed by a processor, cause a computing system to perform operations for automated data collection in cryogenic electron microscopy (cryo-EM), the operations comprising:
identifying, based on patch-level images taken by a cryo-EM instrument, a plurality of holes within a patch of a cryo-EM grid, wherein each identified hole is a candidate data collection point;
estimating an expected reward for each identified hole based on the patch-level images;
determining, using stochastic approximation, a dynamically adjusted threshold quality score representing an estimated optimal time-average reward; and
selecting holes from the identified plurality of holes based on the expected reward by minimizing an objective function that depends on the dynamically adjusted threshold quality score, wherein the dynamically adjusted threshold quality score is based at least in part on observed rewards from the selected holes and microscope operation times.

16. The computer-readable medium of claim 15, wherein the operations further comprise:
determining the microscope operation times including a delay required to refocus the cryo-EM instrument;
adjusting the dynamically adjusted threshold quality score; and
updating a hole predictor based on an observed reward for each hole and the delay.

17. The computer-readable medium of claim 16, wherein the hole predictor includes a machine learning model configured to predict micrograph data quality based on patterns in patch-level hole images, and trained using streaming data acquired during cryo-EM data collection.

18. The computer-readable medium of claim 16, wherein the operations further comprise:
selecting a different plurality of holes within the patch of the cryo-EM grid based on the dynamically adjusted threshold quality score and the observed reward for each hole.

19. The computer-readable medium of claim 15, wherein the operation for estimating an expected reward for each identified hole based on the patch-level images further comprises: determining a maximum expected number of micrographs collected per unit time, or
determining a maximum expected number of particles within each micrograph collected per unit of time,
wherein the micrographs meet the dynamically adjusted threshold quality score collected per unit time.

20. The computer-readable medium of claim 15, wherein the operations further comprise:
dynamically ranking the selected holes from the identified plurality of holes by one or more of the estimated expected reward, an Upper Confidence Bound, or Thompson sampling.
